(19) United States
(12) Patent Application Publication
(10) Pub. No.: US 2015/0187961 A1
(43) Pub. Date: Jul. 2, 2015

(54) PIEZORESISTIVE SENSOR

(71) Applicant: Hyundai Motor Company, Seoul (KR)

(72) Inventors: Dong Gu Kim, Bucheon (KR); Yong Sung Lee, Seongnam (KR); Hiwon Lee, Seoul (KR)

(21) Appl. No.: 14/484,732

(22) Filed: Sep. 12, 2014

(30) Foreign Application Priority Data
Dec. 27, 2013 (KR) 10-2013-0165486

(51) Int. Cl. H01L 29/84

(52) U.S. Cl. CPC H01L 29/84

(57) ABSTRACT

The present disclosure relates to a piezoresistive sensor that improves measurement precision by using a piezoresistive pattern that increases a piezoresistive deformation rate. An embodiment of the present disclosure provides a piezoresistive sensor that may include: a semiconductor substrate, four beams formed as a cross-shape with reference to a central body of the semiconductor substrate, and sixteen piezoresistive patterns formed on a top of the four beams, wherein sixteen piezoresistive patterns are formed as an “X” shape and are disposed on the four beams so as to form four piezoresistive pattern groups.

### CROSS-REFERENCE TO RELATED APPLICATION

This application claims priority to and the benefit of Korean Patent Application No. 10-2013-0165486 filed in the Korean Intellectual Property Office on Dec. 27, 2013, the entire contents of which are incorporated herein by reference.

### BACKGROUND

(a) Technical Field

The present disclosure relates to a piezoresistive sensor. More particularly, the present disclosure relates to the piezoresistive sensor that improves measurement precision by using a piezoresistive pattern increasing a piezoresistive deformation rate.

(b) Description of the Related Art

In general, a six-axis force-torque sensor has a plurality of strain gauges that are attached to a structural body, which generate mechanical deformation and measure applied force and torque. In this manner, the strain gauges need to be attached in consideration of a direction in which force is applied, and in a position at which maximum deformation occurs. However, the aforementioned manner can cause errors, and these errors result in measurement inaccuracies within a range of 2% to 5%.

Recently, a method has been researched where a piezoresistive pattern is manufactured on a silicon surface through a semiconductor process, and the piezoresistive pattern is attached to a structural body which generates deformation, and measures force and torque. This method can decrease an error of attaching position and reduce production cost because it does not use a plurality of strain gauges. Therefore, a piezoresistive sensor has been recently used as the six-axis force-torque sensor, and the piezoresistive sensor has been developed variously as a pressure sensor or an acceleration sensor, for example, by using the piezoresistive effect. The measurement precision of the piezoresistive sensor using a piezoresistive pattern may be changed depending on the type of piezoresistive pattern. Thus, the piezoresistive deformation rate of the piezoresistive sensor should be increased for improving measurement precision.

The above information disclosed in this Background section is only for enhancement of understanding of the background of the disclosure, and therefore it may contain information that does not form the related art that is already known in this country to a person of ordinary skill in the art.

### SUMMARY

The contents of the present disclosure have been made in an effort to provide a piezoresistive sensor having advantages of improving measurement precision by using a piezoresistive pattern increasing a piezoresistive deformation rate.

An exemplary embodiment of the present disclosure provides a piezoresistive sensor that may include: a semiconductor substrate; four beams formed as a cross shape with reference to a central body of the semiconductor substrate; and sixteen piezoresistive patterns formed on the top of the four beams, wherein the sixteen piezoresistive patterns are formed as an “X” shape and disposed on the four beams so as to form four piezoresistive pattern groups.

Each of the four piezoresistive pattern groups may include four piezoresistive patterns. The piezoresistive sensor may further include an electrode pad connecting the four piezoresistive patterns included in the four piezoresistive pattern groups with each other. The electrode pad may be formed on each of the four beams. The four piezoresistive patterns included in the four piezoresistive pattern groups are connected as an “X” shape by the electrode pad. Two piezoresistive patterns of the four piezoresistive patterns included in the four piezoresistive pattern groups may be connected to a central body of the semiconductor substrate. Each piezoresistive deformation rate of the sixteen piezoresistive patterns may be measured so as to detect force (Fx, Fy, Fz) and torque (Mx, My, Mz).

According to an exemplary embodiment of the present disclosure as described above, a piezoresistive deformation rate of the piezoresistive sensor is increased under the same force and torque. Thus, measurement precision of the piezoresistive sensor can be improved.

### BRIEF DESCRIPTION OF THE DRAWINGS

FIG. 1 is a top plan view schematically illustrating a piezoresistive sensor according to an embodiment of the present disclosure.

FIG. 2 is a top plan view schematically illustrating a piezoresistive sensor according to an embodiment of the present disclosure.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment. Further, the drawings and description are to be regarded as illustrative in nature and not restrictive. Like reference numerals designate like elements throughout the specification.

### DETAILED DESCRIPTION OF THE EMBODIMENTS

The contents of the present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise” and variations such as “comprises” or “comprising” will be understood to imply the inclusion of stated elements but not the exclusion of any other elements.

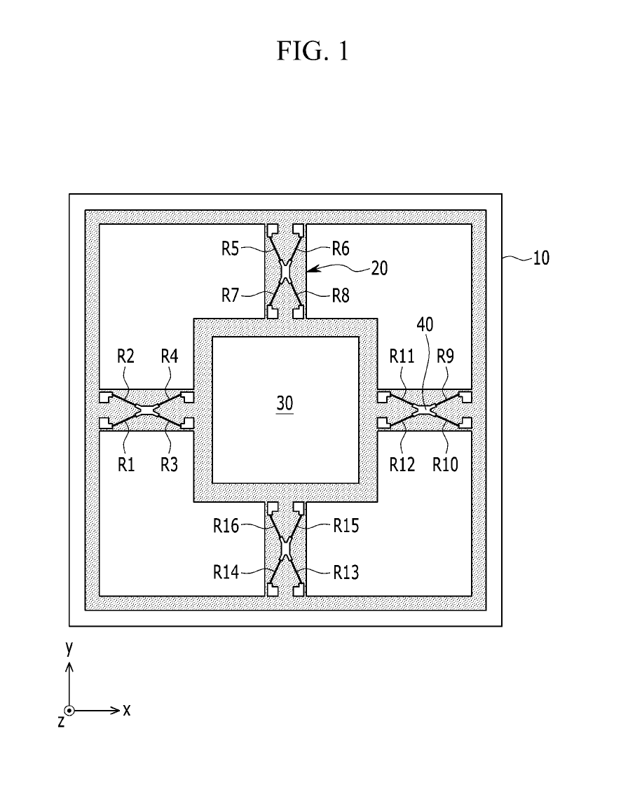

FIG. 1 is a top plan view schematically illustrating a piezoresistive sensor according to an embodiment of the present disclosure.

Referring to FIG. 1, a piezoresistive sensor includes a semiconductor substrate 10, four beams 20 formed on the semiconductor substrate 10, sixteen piezoresistive patterns R1 to R16 formed on the four beams 20, a central body 30 deforming the piezoresistive patterns R1 to R16, and an electrode pad 40 formed on each of the four beams 20. The four beams 20 are formed as a cross-shape with reference to the central body 30. For example, two beams 20 may be formed in an X-axis direction, and the other two beams 20 may be formed as a Y-axis direction.

The sixteen piezoresistive patterns R1 to R16 form four piezoresistive pattern groups R1 to R4, R5 to R8, R9 to R12, and R13 to R16. Each of the piezoresistive pattern groups R1 to R4, R5 to R8, R9 to R12, and R13 to R16 is formed as an “X” shape and are respectively disposed on the four beams 20. Four piezoresistive patterns formed as an “X” shape are connected to the electrode pad 40. Two of the four piezoresistive patterns are connected to the central body 30. That is, four piezoresistive patterns are connected as an “X” shape by the electrode pads 40.

As shown in FIG. 1, four piezoresistive patterns from R1 to R4 are formed as an “X” shape, and a piezoresistive pattern R3 and a piezoresistive pattern R4 may be connected to the central body 30. Four piezoresistive patterns from R5 to R8 are formed as an “X” shape, and a piezoresistive pattern R7 and a piezoresistive pattern R8 may be connected to the central body 30. Four piezoresistive patterns from R9 to R12 are formed as an “X” shape, and a piezoresistive pattern R11 and a piezoresistive pattern R12 may be connected to the central body 30. Four piezoresistive patterns from R13 to R16 are formed as an “X” shape, and a piezoresistive pattern R15 and a piezoresistive pattern R16 may be connected to the central body 30.

Each piezoresistive deformation rate of the sixteen piezoresistive patterns R1 to R16 may be measured so as to detect force (Fx, Fy, Fz) and torque (Mx, My, Mz) generated between two axis directions. That is, the piezoresistive sensor may be used as a six-axis force-torque sensor. The sixteen piezoresistive patterns R1 to R16 may be formed by a Wheatstone bridge circuit, so force (Fx, Fy, Fz) and torque (Mx, My, Mz) generated between two axis directions may be detected by the Wheatstone bridge circuit.

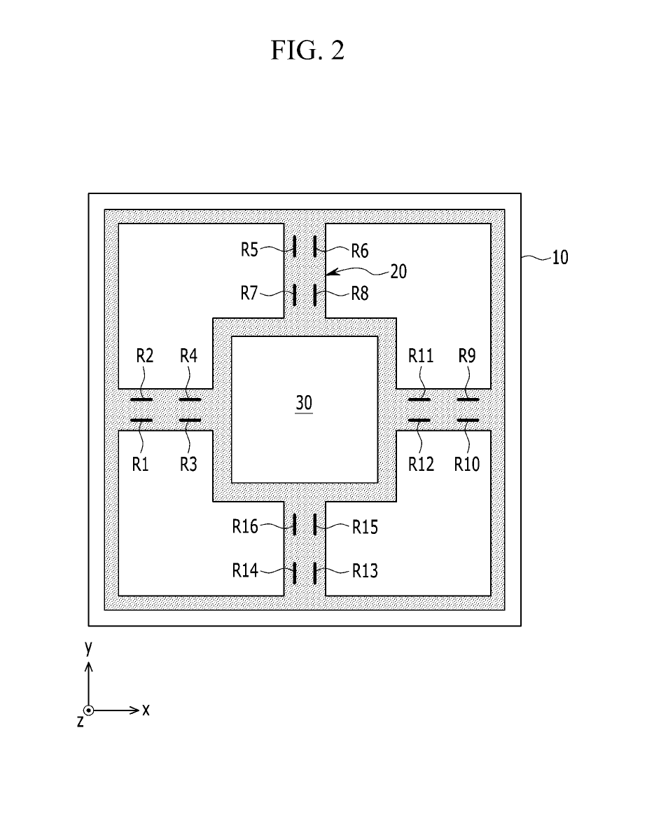

FIG. 2 is a top plan view schematically illustrating a piezoresistive sensor according to an embodiment of the present disclosure.

In FIG. 2, sixteen piezoresistive patterns R1 to R16 form four piezoresistive pattern groups R1 to R4, R5 to R8, R9 to R12, and R13 to R16 similarly, but in contrast to the piezoresistive patterns illustrated in FIG. 1, each of the piezoresistive pattern groups R1 to R4, R5 to R8, R9 to R12, and R13 to R16 may be formed as an “II” shape instead of an “X” shape.

Hereinafter, measurement precision of the piezoresistive sensor in which each of the piezoresistive pattern groups R1 to R4, R5 to R8, R9 to R12, and R13 to R16 is formed as an “X” shape in FIG. 1 and an “II” shape in FIG. 2 will be described. When the piezoresistive deformation rate of sixteen piezoresistive patterns R1 to R16 increases, the measurement precision of the piezoresistive sensor becomes more accurate. Therefore, the piezoresistive deformation rate of sixteen piezoresistive patterns R1 to R16 formed as an “X” shape in FIG. 1 will hereinafter be compared with the piezoresistive deformation rate of sixteen piezoresistive patterns R1 to R16 formed as an “II” shape in FIG. 2.

To this end, Table 1 shows the piezoresistive deformation rate of the sixteen piezoresistive patterns R1 to R16 to which a force Fx is applied. The unit of the piezoresistive deformation rate is 10⁻⁵e.

TABLE 1

| | R1 | R2 | R3 | R4 | R5 | R6 | R7 | R8 |
|---|---|---|---|---|---|---|---|---|
| II shape | 7.43 | 6.25 | 6.22 | 7.44 | 2.99 | −2.78 | 2.79 | −3.0 |
| X shape | 7.57 | 6.34 | 6.33 | 7.58 | 3.34 | −3.1 | 3.1 | −3.33 |
| Deformation | 1.9 | 1.4 | 1.7 | 1.8 | 11.6 | 11.5 | 11.1 | 11.1 |
| rate (%) | | | | | | | | |
| | R9 | R10 | R11 | R12 | R13 | R14 | R15 | R16 |
| II shape | −7.44 | −6.22 | −6.22 | −7.44 | −3.0 | 2.78 | −2.78 | 3.0 |
| X shape | −7.57 | −6.34 | −6.33 | −7.58 | −3.34 | 3.1 | −3.1 | 3.34 |
| Deformation | 1.8 | 1.6 | 1.7 | 1.9 | 11.4 | 11.4 | 11.3 | 11.1 |
| rate (%) | | | | | | | | |

When the force Fx is applied, the piezoresistive deformation rate of the sixteen piezoresistive patterns R1 to R16 formed as an “X” shape in FIG. 1 is an average of 6.5% higher than the piezoresistive deformation rate of the sixteen piezoresistive patterns R1 to R16 formed as an “II” shape in FIG. 2.

Table 2 shows the piezoresistive deformation rates of the sixteen piezoresistive patterns R1 to R16 to which a force Fz is applied. The unit of the piezoresistive deformation rate is 10⁻⁴e.

TABLE 2

| | R1 | R2 | R3 | R4 | R5 | R6 | R7 | R8 |
|---|---|---|---|---|---|---|---|---|
| II shape | −1.41 | 1.6 | 1.62 | −1.4 | −1.4 | 1.6 | 1.62 | −1.4 |
| X shape | −1.44 | 1.63 | 1.64 | −1.44 | −1.44 | 1.63 | 1.64 | −1.43 |
| Deformation | 2.6 | 1.7 | 1.2 | 2.7 | 3.0 | 1.6 | 1.1 | 2.6 |
| rate (%) | | | | | | | | |
| | R9 | R10 | R11 | R12 | R13 | R14 | R15 | R16 |
| II shape | −1.4 | 1.61 | 1.62 | −1.4 | −1.4 | 1.61 | 1.62 | −1.4 |
| X shape | −1.44 | 1.63 | 1.64 | −1.44 | −1.44 | 1.63 | 1.64 | −1.44 |
| Deformation | 2.6 | 1.4 | 1.1 | 2.7 | 2.8 | 1.4 | 1.1 | 2.8 |
| rate (%) | | | | | | | | |

When the force Fz is applied, the piezoresistive deformation rate of the sixteen piezoresistive patterns R1 to R16 formed as an “X” shape in FIG. 1 is an average of 2% higher than the piezoresistive deformation rate of the sixteen piezoresistive patterns R1 to R16 formed as an “II” shape in FIG. 2.

Table 3 shows the piezoresistive deformation rates of the sixteen piezoresistive patterns R1 to R16 to which a torque Mx is applied. The unit of piezoresistive deformation rate is 10⁻⁵e.

TABLE 3

| | R1 | R2 | R3 | R4 | R5 | R6 | R7 | R8 |
|---|---|---|---|---|---|---|---|---|
| II shape | −3.03 | 2.31 | 2.32 | −2.99 | 9.35 | −9.33 | 9.33 | −9.32 |
| X shape | −3.04 | 2.34 | 2.34 | −3.01 | 9.28 | −9.35 | 9.34 | −9.28 |
| Deformation | 0.0 | 1.2 | 0.9 | 0.4 | −0.7 | 0.3 | 0.1 | −0.4 |
| rate (%) | | | | | | | | |
| | R9 | R10 | R11 | R12 | R13 | R14 | R15 | R16 |
| II shape | 3.03 | −2.31 | −2.32 | 3.01 | −9.32 | 9.35 | −9.31 | 9.33 |
| X shape | 3.05 | −2.33 | −2.34 | 3.03 | −9.3 | 9.34 | −9.34 | 9.29 |
| Deformation | 0.7 | 1.0 | 0.8 | 0.5 | −0.1 | −0.1 | 0.3 | −0.5 |
| rate (%) | | | | | | | | |

When the torque Mx is applied, the piezoresistive deformation rate of the sixteen piezoresistive patterns R1 to R16 formed as an “X” shape in FIG. 1 is an average of 0.2% higher than the piezoresistive deformation rate of the sixteen piezoresistive patterns R1 to R16 formed as an “II” shape in FIG. 2.

Table 4 shows the piezoresistive deformation rates of the sixteen piezoresistive patterns R1 to R16 to which a torque Mz applied. The unit of piezoresistive deformation rate is 10⁻⁵e.

TABLE 4

| | R1 | R2 | R3 | R4 | R5 | R6 | R7 | R8 |
|---|---|---|---|---|---|---|---|---|
| II shape | −5.05 | 7.32 | −7.33 | 5.07 | −5.04 | 7.31 | −7.34 | 5.07 |
| X shape | −5.44 | 7.99 | −8.01 | 5.46 | −5.44 | 7.99 | −8.01 | 5.46 |
| Deformation | 7.8 | 9.1 | 9.3 | 7.7 | 7.9 | 9.3 | 9.2 | 7.7 |
| rate (%) | | | | | | | | |
| | R9 | R10 | R11 | R12 | R13 | R14 | R15 | R16 |
| II shape | −5.04 | 7.3 | −7.33 | 5.07 | −5.05 | 7.31 | −7.34 | 5.07 |
| X shape | −5.43 | 7.98 | −8.01 | 5.47 | −5.45 | 7.98 | −8.02 | 5.46 |
| Deformation | 7.6 | 9.4 | 9.3 | 8.0 | 7.9 | 9.3 | 9.3 | 7.7 |
| rate (%) | | | | | | | | |

When the torque Mz is applied, the piezoresistive deformation rate of the sixteen piezoresistive patterns R1 to R16 formed as an “X” shape in FIG. 1 is an average of 8.5% higher than the piezoresistive deformation rate of the sixteen piezoresistive patterns R1 to R16 formed as an “II” shape in FIG. 2.

As can be seen from the experiment results in Tables 1 to 4, measurement precision of the piezoresistive sensor in which the sixteen piezoresistive patterns R1 to R16 are formed as an “X” shape (as shown in FIG. 1) is greater than that of the piezoresistive sensor in which the sixteen piezoresistive patterns R1 to R16 are formed as an “II” shape (as shown in FIG. 2).

The accompanying drawings and the detailed description of the present disclosure are only illustrative, and are for the purpose of describing the contents of the disclosure, but are not meant to limit the meanings or scope of the embodiments, as described in the claims. Therefore, it will be appreciated by those skilled in the art that various modifications and other equivalent embodiments can be made. Accordingly, the scope of the present disclosure must be determined by the scope of the claims and equivalents, not by the described embodiments.

### DESCRIPTION OF SYMBOLS

10: semiconductor substrate
20: beam
30: central body
40: electrode pad
R1 to R16: piezoresistive pattern

What is claimed is:

1. A piezoresistive sensor comprising:
a semiconductor substrate;
four beams formed as a cross-shape with reference to a central body of the semiconductor substrate; and
sixteen piezoresistive patterns formed on a top of the four beams,
wherein the sixteen piezoresistive patterns are formed as an “X” shape and disposed on the four beams so as to form four piezoresistive pattern groups.

2. The piezoresistive sensor of claim 1, wherein each of the four piezoresistive pattern groups includes four piezoresistive patterns.

3. The piezoresistive sensor of claim 2, further comprising an electrode pad connecting the four piezoresistive patterns included in the four piezoresistive pattern groups with each other.

4. The piezoresistive sensor of claim 3, wherein the electrode pad is formed on each of the four beams.

5. The piezoresistive sensor of claim 3, wherein the four piezoresistive patterns included in the four piezoresistive pattern groups are connected as an “X” shape by the electrode pad.

6. The piezoresistive sensor of claim 5, wherein two piezoresistive patterns of the four piezoresistive patterns included in the four piezoresistive pattern groups are connected to the central body of the semiconductor substrate.

7. The piezoresistive sensor of claim 6, wherein each piezoresistive deformation rate of the sixteen piezoresistive patterns is measured so as to detect force (Fx, Fy, Fz) and torque (Mx, My, Mz).

8. A piezoresistive sensing system comprising:
a semiconductor substrate; and
a piezoresistive sensor including four beams formed as a cross-shape with reference to a central body of the semiconductor substrate and sixteen piezoresistive patterns formed on a top of the four beams,
wherein the sixteen piezoresistive patterns are formed as an “X” shape and disposed on the four beams so as to form four piezoresistive pattern groups.
